(19) United States
(12) Patent Application Publication
(10) Pub. No.: US 2024/0162355 A1
(43) Pub. Date: May 16, 2024

(54) CHIP LEVEL PACKAGE PHOTODIODE

(71) Applicant: Vishay Semiconductor GmbH, Heilbronn (DE)

(72) Inventor: Manuel Schmidt, Waghaeusel (DE)

(73) Assignee: Vishay Semiconductor GmbH, Heilbronn (DE)

(21) Appl. No.: 17/987,507

(22) Filed: Nov. 15, 2022

(51) Int. Cl. H01L 31/0224; H01L 31/02; H01L 31/103; H01L 31/18

(52) U.S. Cl. CPC H01L 31/022408; H01L 31/02005; H01L 31/103; H01L 31/1804

(57) ABSTRACT

A chip level package photodiode includes a first conductive layer located at a first side of the chip level package photodiode. A first contact is located at a second side of the chip level package photodiode. A dopant diffusion layer is formed between the first conductive layer and the first contact electrically connecting the first conductive layer to the first contact, the dopant diffusion layer proceeding from the first side of the chip level package photodiode to the second side of the chip level package photodiode completely through a depletion zone of the chip level package photodiode.

### BACKGROUND

Conventional photodiodes include an anode on the top of the photodiode and a cathode on the bottom side of the photodiode. However, both the anode and the cathode must include a contact that is connected to a printed circuit board (PCB) in order to provide a signal from the photodiode for processing.

### BRIEF DESCRIPTION OF THE DRAWINGS

A more detailed understanding can be had from the following description, given by way of example in conjunction with the accompanying drawings wherein:

FIG. 1 is a cross-section of a conventional photodiode;

FIG. 2 is a cross-section of an integrated circuit chip including through silicon vias;

FIG. 3 is a cross-section of a chip level package photodiode according to an example embodiment; and

FIG. 4 is a flow diagram illustrating an example method of forming a chip level package photodiode according to an example embodiment.

### DETAILED DESCRIPTION

Chip level packages are a technology that allows direct soldering of semiconductor dies to a printed circuit board (PCB). Chip level packages, as opposed to having a die encapsulated into a package, generally have smaller sizing in lateral dimensions and also in height. Additionally, the cost of manufacturing a chip level package may be less than manufacturing a conventional die encapsulated into a package.

Usually in a chip level package, solder contacts, as well as active semiconductor structures are on the bottom side of the die, with the top side being used for marking. Accordingly, no electrical connections between the bottom and top sides are necessary in a chip level package.

A chip level package for photodiodes allows a photodiode to be a smaller size and height. This may be beneficial in all applications with space constraints, for example in the area of a wearable devices (e.g., heart rate monitoring and pulse oximetry).

However, photodiode's active structures, (e.g., a pn-junction diode), cannot be located on the bottom side of the device without significant performance reduction. That is, most of the light absorption by the photodiode, especially for short wavelengths, would occur outside of the depletion zone. This may result in reduced sensitivity by recombination loss and extremely slow rise and fall times caused by carrier diffusion.

Although further detail will be provided below, briefly, a chip level photodiode is described. The chip level photodiode is capable of being attached, via soldering for example, to a printed circuit board.

A chip level package photodiode includes a first conductive layer located at a first side of the chip level package photodiode. A first contact is located at a second side of the chip level package photodiode. A dopant diffusion layer is formed between the first conductive layer and the first contact electrically connecting the first conductive layer to the first contact, the dopant diffusion layer proceeding from the first side of the chip level package photodiode to the second side of the chip level package photodiode completely through a depletion zone of the chip level package photodiode.

A method of forming a chip level package photodiode includes forming a first conductive layer located at a first side of the chip level package photodiode. A first contact is formed located at a second side of the chip level package photodiode. A dopant diffusion layer is formed between the first conductive layer and the first contact electrically connecting the first conductive layer to the first contact, the dopant diffusion layer proceeding from the first side of the chip level package photodiode to the second side of the chip level package photodiode completely through a depletion zone of the chip level package photodiode.

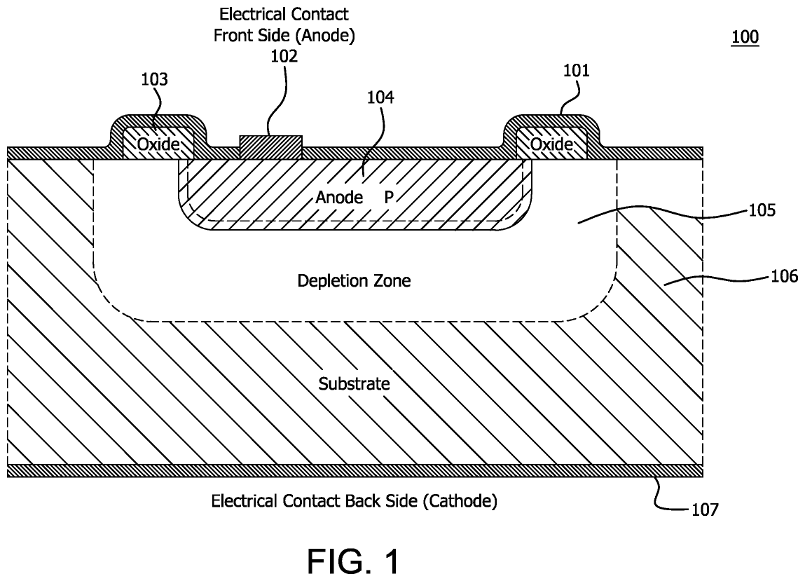

FIG. 1 is a cross-section of a conventional photodiode 100. For purposes of example, an n-substrate photodiode is shown. However, it should be noted that the opposite polarity, for example, utilizing a p-type substrate may also be implemented.

Although the operation of the conventional photodiode is described below, briefly, the conventional photodiode 100 includes an antireflection coating (e.g., nitride) 101, a front side electrical contact (e.g., anode) 102, an oxide coverage 103 over a resulting pn-junction 103, a p-type anode layer 104 located at the top side (light incident side) of the die, a depletion zone 105 an n-substrate 106 and a back side electrical contact (e.g. cathode) 107.

An incident photon is absorbed by the semiconductor material of the photodiode and will create an electron hole pair. The penetration depth of the photon depends on its wavelength. Shorter wavelengths will have lower penetration depths than longer wavelengths.

If the absorption happens within the depletion zone 105 of the pn-junction, the electrical field will separate both carriers immediately resulting in a photocurrent. If the absorption happens below the depletion zone 105, both carriers will show a random diffusion movement.

If one of the carriers diffuses into the depletion zone, it will also create a photocurrent. In this case there are two possible disadvantages which disturb the photodiode performance. In one case, due to the duration of the diffusion process, the electrical current will be delayed. Additionally, it is also possible that the generated carriers get lost by recombination before they can reach the depletion zone. This results in reduced sensitivity of the photodiode.

For these reasons, a photodiode having the active structures on the backside (as usual for standard die level package devices) may have a significantly reduced performance concerning sensitivity and reaction time.

In the example shown in FIG. 1, the anode contact is on the top (light incident) side of the die, and the cathode contact is on the backside of the die. As both, anode and cathode are accessible from the topside, it is also possible to have both contacts on the topside. But for creating both contacts on the bottom side which is necessary for attaching the die by, for example, SMD soldering as a die level package, an additional electrical connection of the anode to the backside of the device would be necessary.

One way of making electrical connections in chip is to utilize through silicon vias (TSVs). TSVs are areas where an electrical conductor is filled in an area that coincides with a conductor from a layer above or below to provide an electrical connection between silicon layers.

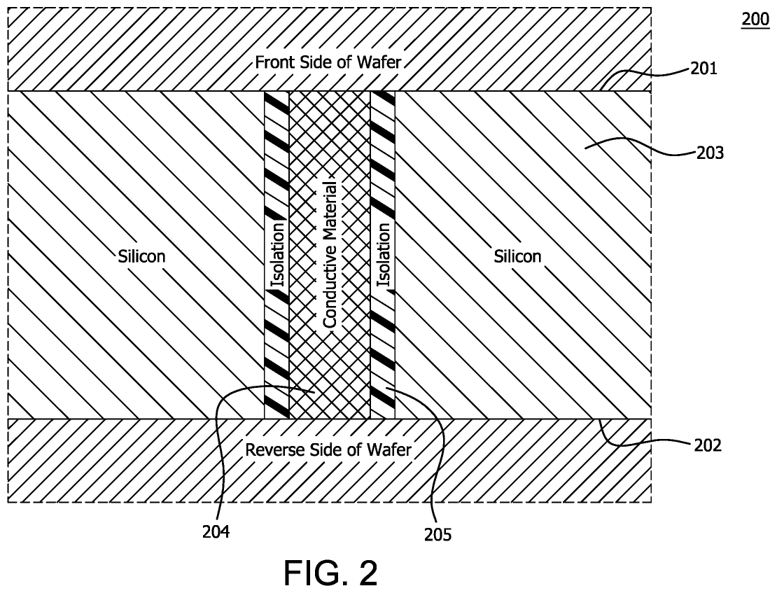

FIG. 2 is a cross-section of an integrated circuit chip 200 including TSVs. As shown in FIG. 2, the integrated circuit chip 200 includes a front side of a wafer 201 and a reverse side of the wafer 202. A silicon layer 203 exists between the front side of the wafer 201 and the reverse side of the wafer 202.

In order to connect the front side to the back side of the wafer, a through silicon via may be utilized. The TSV includes a conductive material 204 and isolation regions 205. In this manner, the conductive material 204 provides a connection between the front side of the wafer 201 and the reverse side of the wafer 202 while being isolated from the silicon layer 203.

A conventional means of production of TSVs is based on a vertical etching process (e.g., Bosch process) followed by sidewall passivation and filling of the hole with conductive material (e.g., poly-Silicon). The residue of passivation and filling material are removed from the top and bottom surface of the wafer being formed in the chip. Accordingly, the process may be an expensive process and significantly increases the costs of a die.

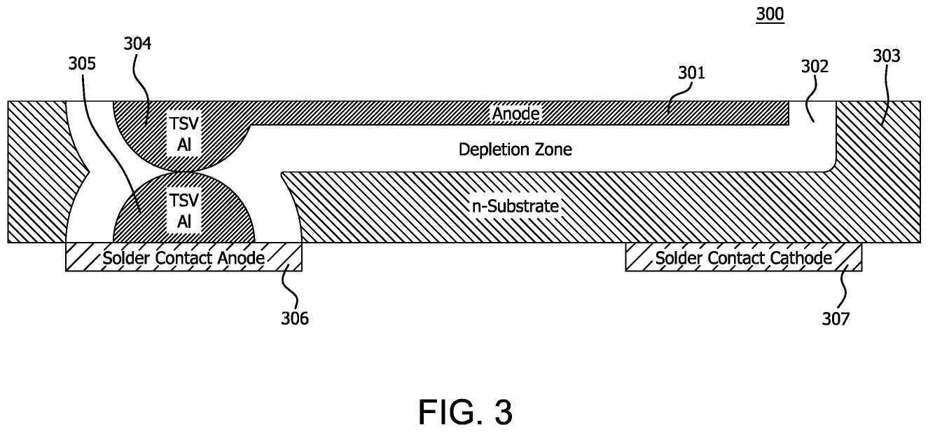

FIG. 3 is a cross-section of a chip level package photodiode 300 according to an example embodiment. The chip level package photodiode includes a first conductive layer (e.g., anode) 301, depletion zone (region) 302, a second conductive layer (e.g., n-Substrate layer) 303, first p-diffusion layer 304, second p-diffusion diffusion layer 305, solder contact anode 306 and solder contact cathode 307.

As shown in FIG. 3, rather than utilize TSVs to connect the first conductive layer 301 to the contact anode 306 below, a deep diffusion layer is utilized. That is, the first p-diffusion layer 304, which may be formed by aluminum as a dopant in silicon, is diffused downward from the anode 301. The second p-diffusion layer 305, which may also be formed by aluminum as a dopant in silicon, is formed from the solder contact anode 306 upward toward the first p-diffusion layer 304.

The connection of the two diffusion layers (304 and 305) provides an electrical connection between the first conductive layer 301 and the contact anode 306. In this manner, the first conductive layer 301 may be formed on a first side (e.g., top side) of the chip level package photodiode 300, while the contact anode 306 may be formed on a second side (e.g., bottom side) of the chip level package photodiode 300.

Alternatively, it is also possible to create the electrical connection by only one diffused layer starting either from the bottom or the top side of the wafer, in this case the diffusion time would be longer.

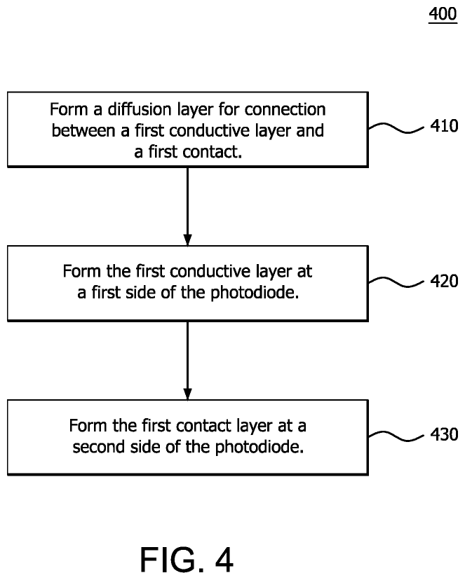

FIG. 4 is a flow diagram illustrating an example method 400 of forming a chip level package photodiode according to an example embodiment.

In a first step (step 410), a dopant diffusion layer is formed for connection between the first conductive layer and a first contact (e.g., the solder contact anode 306). As described above in FIG. 3, the dopant diffusion layer may include the first p-diffusion layer being formed from the first side of the chip level package photodiode toward the second side of the chip level package photodiode.

A second dopant diffusion layer (e.g., the second p-diffusion layer of FIG. 3) may be formed upward from the first contact on the bottom of the chip level package photodiode toward the top of the chip level package photodiode.

The first and second dopant diffusion layers are connected to complete an electrical connection between the first conductive layer at the top of the chip level package photodiode and the anode contact at the bottom of the chip level package photodiode.

In a second step the photodiode structure is created on the top side of the chip. That is, the first conductive layer is formed at the first side of the chip level package photodiode (step 420).

In the third step, the solder contacts are created at the bottom side of the chip. For example, the first contact layer is formed at the second side of the photodiode (step 430).

Although the steps may be performed in any order and additional steps may be utilized, such as to form the second conductive layer (e.g., n-substrate 303 of FIG. 3), it may be desirable to perform step 410 prior to any other step of the method 400 as well as any other steps that may be performed. If step 410 is performed after, for example, step 420 and 430, the resulting process to perform steps 420 and 430 could result in the destruction of the dopant diffusion layer or layers.

It should be understood that many variations are possible based on the disclosure herein. Although features and elements are described above in particular combinations, each feature or element can be used alone without the other features and elements or in various combinations with or without other features and elements.

For example, as mentioned above, the photodiode described is shown with a p-layer anode conductive layer and an n-substrate layer as the cathode. However, the reverse embodiment may also be utilized. In addition, the dopant diffusion layer may be an aluminum dopant diffusion layer or another type of metallized diffusion layer.

The photodiodes described above may be formed of silicon or any other appropriate material. Additionally, the photodiodes described above may include blue-enhanced photodiodes.

By providing contacts on a single side of the photodiode, it may be possible to make the photodiode a smaller package that can be implemented in smaller devices. For example, it may be possible to make a wearable photodiode by allowing the light incident side to be connected to a contact on the side where the photodiode is mounted or worn.

1. A chip level package photodiode, comprising:
a first conductive layer located at a first side of the chip level package photodiode;
a first contact located at a second side of the chip level package photodiode; and
a dopant diffusion layer formed between the first conductive layer and the first contact electrically connecting the first conductive layer to the first contact, the dopant diffusion layer proceeding from the first side of the chip level package photodiode to the second side of the chip level package photodiode completely through a depletion zone of the chip level package photodiode.

2. The chip level package photodiode of claim 1, further comprising:
a second conductive layer located at the second side of the chip level package photodiode; and
a second contact located at the second side of the chip level package photodiode, the second contact in electrical communication with the second conductive layer.

3. The chip level package photodiode of claim 2 wherein the first conductive layer is a p-substrate layer.

4. The chip level package photodiode of claim 3 wherein the first contact is an anode.

5. The chip level package photodiode of claim 3 wherein the second conductive layer is an n-substrate layer.

6. The chip level package photodiode of claim 5 wherein the second contact is a cathode.

7. The chip level package photodiode of claim 1 wherein the dopant diffusion layer is aluminum.

8. The chip level package photodiode of claim 1 wherein the dopant diffusion layer is formed from the first side to the second side.

9. The chip level package photodiode of claim 1 wherein the dopant diffusion layer includes a first dopant diffusion portion formed from the first side to the second side and a second dopant diffusion portion formed from the second side to the first side connecting to the first dopant diffusion portion.

10. The chip level package photodiode of claim 1 wherein the chip level package photodiode is a blue-enhanced photodiode.

11. A method of forming a chip level package photodiode, comprising:
forming a first conductive layer located at a first side of the chip level package photodiode;
forming a first contact located at a second side of the chip level package photodiode; and
forming a dopant diffusion layer formed between the first conductive layer and the first contact electrically connecting the first conductive layer to the first contact, the dopant diffusion layer proceeding from the first side of the chip level package photodiode to the second side of the chip level package photodiode completely through a depletion zone of the chip level package photodiode.

12. The method of claim 11, further comprising:
forming a second conductive layer located at the second side of the chip level package photodiode; and
forming a second contact located at the second side of the chip level package photodiode, the second contact in electrical communication with the second conductive layer.

13. The method of claim 12 wherein the first conductive layer is a p-substrate layer.

14. The method of claim 13 wherein the first contact is an anode.

15. The method of claim 13 wherein the second conductive layer is an n-substrate layer.

16. The method of claim 15 wherein the second contact is a cathode.

17. The method of claim 11 wherein the dopant diffusion layer is aluminum.

18. The method of claim 11, further comprising forming the dopant diffusion layer from the first side to the second side.

19. The method of claim 11 wherein the forming the dopant diffusion layer includes forming a first dopant diffusion portion from the first side to the second side, forming a second dopant diffusion portion from the second side to the first side, and connecting to the first dopant diffusion portion.

20. The method of claim 11 wherein the chip level package photodiode is a blue-enhanced photodiode.
